(19) United States
(12) Patent Application Publication
(10) Pub. No.: US 2021/0175043 A1
(43) Pub. Date: Jun. 10, 2021

(54) Methods and Apparatus For Controlling Contaminant Deposition on a Dynode Electron-Emissive Surface

(71) Applicant: ADAPTAS SOLUTIONS PTY LTD, Clyde, New South Wales (AU)

(72) Inventors: Wayne Sheils, Clyde, New South Wales (AU); Toby Shanley, Clyde, New South Wales (AU)

(21) Appl. No.: 16/754,802

(22) PCT Filed: Aug. 29, 2018
(86) PCT No.: PCT/AU2018/050930

§ 371 Date: Apr. 9, 2020

(30) Foreign Application Priority Data
Oct. 9, 2017 (AU) 2017904061

(51) Int. Cl. H01J 9/00; H01J 43/10; B08B 7/00

(52) U.S. Cl. CPC H01J 9/00; H01J 2209/017; B08B 7/0035; H01J 43/10

(57) ABSTRACT

Components of scientific analytical equipment, and particularly to methods for extending the operational lifetime or otherwise improving the performance of dynodes used in electron multipliers. The method includes: (i) increasing the secondary electron yield of a dynode and/or (ii) decreasing the rate of degradation of electron yield of a dynode, by exposing a dynode electron-emissive surface to an electron flux under conditions causing electron-impact induced removal of a contaminant deposited on the dynode electron-emissive surface. The conditions may be selected such that the electron-mediated removal is enhanced relative to a contaminant deposition process so as to provide a net decrease in the rate of contaminant deposition and/or a decrease in the amount of contaminant present on the dynode electron-emissive surface.

### FIELD OF THE INVENTION

The present invention relates to generally to components of scientific analytical equipment. More particularly, the invention relates to methods for extending the operational lifetime or otherwise improving the performance of dynodes used in electron multipliers.

### BACKGROUND TO THE INVENTION

In many scientific applications, it is necessary to amplify an electron signal. For example, in a mass spectrometer the analyte is ionized to form a range of charged particles (ions). The resultant ions are then separated according to their mass-to-charge ratio, typically by acceleration and exposure to an electric or magnetic field. The separated signal ions impact on an ion detector surface to generate one or more secondary electrons. Results are displayed as a spectrum of the relative abundance of detected ions as a function of the mass-to-charge ratio.

In other applications the particle to be detected may not be an ion, and may be a neutral atom, a neutral molecule, or an electron. In any event, a detector surface is still provided upon which the particles impact.

The secondary electrons resulting from the impact of an input particle on the impact surface of a detector are typically amplified by an electron multiplier. Electron multipliers generally operate by way of secondary electron emission whereby the impact of a single or multiple particles on the multiplier impact surface causes single or (preferably) multiple electrons associated with atoms of the impact surface to be released.

One type of electron multiplier is known as a discrete-dynode electron multiplier. Such multipliers include a series of surfaces called dynodes, with each dynode in the series set to increasingly more positive voltage. Each dynode is capable of emitting one or more electrons upon impact from secondary electrons emitted from previous dynodes, thereby amplifying the input signal.

Another type of electron multiplier operates using a single continuous dynode. In these versions, the resistive material of the continuous dynode itself is used as a voltage divider to distribute voltage along the length of the emissive surface.

Developments in mass spectrometry instrumentation have led to increases in instrument throughput, with these increases in turn elevating the ion current handled by the dynode-based detector. The detector amplifies the ion current according to a gain factor to provide for the reliable detection of a single ion impact. It is highly desirable for a detector to exhibit a high dynamic range and furthermore be capable of withstanding the extraction of significant output charge.

It is a problem in the art that the sensitivity and gain of dynode-based detectors degrade over time. It is thought that the surfaces of the dynodes slowly become covered with contaminants from the detector vacuum system, causing their secondary electron emission to be reduced and the gain of the electron multiplier to decrease. To compensate for this process, the operating voltage applied to the multiplier must be periodically increased to maintain the required multiplier gain. Ultimately, however, the multiplier will require replacement.

Prior artisans have addressed the problems of dynode ageing by increasing dynode surface area. The increase in surface area acts to distribute the work-load of the electron multiplication process over a larger area, effectively slowing the aging process and improving operating life and gain stability. This approach provides only modest increases in service life, and of course is limited by the size constraints of the detector unit with a mass spectrometry instrument.

It is an aspect of the present invention to overcome or ameliorate a problem of the prior art by providing methods and apparatus for extending the service life of a dynode-based detector. It is a further aspect to provide a useful alternative to the prior art.

The discussion of documents, acts, materials, devices, articles and the like is included in this specification solely for the purpose of providing a context for the present invention. It is not suggested or represented that any or all of these matters formed part of the prior art base or were common general knowledge in the field relevant to the present invention as it existed before the priority date of each claim of this application.

### SUMMARY OF THE INVENTION

In a first aspect, but not necessarily the broadest aspect, the present invention provides a method for: (i) increasing the secondary electron yield of a dynode and/or (ii) decreasing the rate of degradation of electron yield of a dynode, the method comprising the step of exposing a dynode electron-emissive surface to an electron flux under conditions enhancing electron-impact induced chemical removal of a contaminant deposited on the dynode electron-emissive surface.

In one embodiment of the first aspect, the conditions are such that the electron-induced chemical removal is enhanced relative to a contaminant deposition process so as to provide a net decrease in the rate of contaminant deposition and/or a decrease in the amount of contaminant present on the dynode electron-emissive surface.

In one embodiment of the first aspect, the conditions are such that the electron-induced chemical removal has a higher rate than the contaminant deposition process.

In one embodiment of the first aspect, the electron-mediated chemical removal is reliant at least in part on a removal reactant or precursor thereof, the removal reactant or precursor thereof being either inherently present on or about the dynode electron-emissive surface, or deliberately introduced on or about the dynode electron-emissive surface, the removal reactant or precursor thereof being capable under the method conditions of removing or facilitating removal of a contaminant deposited on the dynode electron-emissive surface.

In one embodiment of the first aspect, the removal reactant is capable of donating an electron to the contaminant deposited on the dynode electron-emissive surface, or the precursor is capable of conversion to a removal reactant capable of donating an electron to the contaminant deposited on the dynode electron-emissive surface under the method conditions.

In one embodiment of the first aspect, the removal reactant is involved in a redox reaction with the contaminant deposited on the dynode electron-emissive surface.

In one embodiment of the first aspect, the removal reactant is an oxidant in the context of the redox reaction and the contaminant is a reductant in the context of the redox reaction.

In one embodiment of the first aspect, the removal reactant or precursor thereof is water.

In one embodiment of the first aspect, the removal reactant or precursor thereof is a gas or a vapour or an adsorbate.

In one embodiment of the first aspect, the removal reactant or precursor thereof is not capable of being deposited as a contaminant on the dynode electron-emissive surface.

In one embodiment of the first aspect, the removal reactant or precursor thereof is not carbon-based, is not a hydrocarbon, or does not comprise a carbon atom.

In one embodiment of the first aspect, the method comprises the step of introducing the removal reactant or precursor thereof into a vacuum chamber within which the dynode electron-emissive surface is operable.

In one embodiment of the first aspect, the contaminant deposition process is reliant at least in part on a deposition precursor.

In one embodiment of the first aspect, the deposition precursor is present on or about the dynode electron-emissive surface, or present within the dynode material.

In one embodiment of the first aspect, the deposition precursor is capable of forming a contaminant deposited on the dynode electron-emissive surface, the contaminant deposited on the dynode electron-emissive surface being capable of being involved in a redox reaction with the removal reactant.

In one embodiment of the first aspect, the deposition precursor is carbon-based, is a hydrocarbon, or is a carbon-containing molecule.

In one embodiment of the first aspect, the deposition precursor is a gas or a vapour on or about the dynode electron-emissive surface, or near-by surfaces, or a dynode surface-associated substance.

In one embodiment of the first aspect, the removal reactant precursor is present on or about the dynode electron-emissive surface at a higher concentration or in higher amounts compared with the deposition precursor.

In one embodiment of the first aspect, the removal reactant precursor and the deposition precursor are both gases, and the removal reactant precursor is present at a higher partial pressure than the deposition precursor.

In one embodiment of the first aspect, the electron current density of the electron flux impacting the dynode emissive surface is controlled so as to enhance electron-induced chemical removal of a contaminant over deposition of the contaminant on the dynode electron-emissive surface.

In one embodiment of the first aspect, the electron current density is controlled to an upper or lower limit of a range, or within the range limits, whereby in circumstances where contaminant deposition rate is mass transport-limited, any increase in electron current density does not increase the contaminant deposition rate.

In one embodiment of the first aspect, the electron current density is controlled to an upper or lower limit of a range, or within the range limits, whereby any increase in electron density increases the rate of contaminant removal.

In one embodiment of the first aspect, the electron current density is controlled to an upper or lower limit of a range, within the range limits, whereby any increase in electron current density increases the rate of contaminant removal with electron current density but does not proportionally increase rate of contaminant deposition.

In one embodiment of the first aspect, the method is applied to a series of discrete dynodes in an amplification chain, and the method comprises the step of controlling electron current density differentially between the dynodes in the chain such that the flux density is relatively low for dynodes for which contaminant deposition rate is electron-limited, and relatively high for dynodes for which the contaminant deposition rate is deposition precursor-limited.

In a second aspect, the present invention provides an electron multiplier comprising a series of discrete dynodes or a continuous dynode, the electron multiplier comprising means for controlling the amount, concentration, or partial pressure of a removal reactant on or about one or more dynode emissive surfaces.

In one embodiment of the second aspect, the electron multiplier comprises means for introducing a removal reactant or precursor thereof on or about one or more dynode electron-emissive surfaces.

In one embodiment of the second aspect, the means for introducing a removal reactant or precursor thereof comprises a removal reactant or precursor thereof source.

In one embodiment of the second aspect, the electron multiplier further comprises a conduit configured to convey a removal reactant or precursor thereof onto or about one or more dynode electron-emissive surfaces.

In one embodiment of the second aspect, the removal reactant is capable of donating an electron to a contaminant deposited on the dynode electron-emissive surface, or the precursor is capable of conversion to a removal reactant capable of donating an electron to the contaminant deposited on the dynode electron-emissive surface under the method conditions.

In one embodiment of the second aspect, the removal reactant is involved in a redox reaction with the contaminant deposited on the dynode electron-emissive surface.

In one embodiment of the second aspect, the removal reactant is an oxidant in the context of the redox reaction and the contaminant is a reductant in the context of the redox reaction.

In one embodiment of the second aspect, the removal reactant or precursor thereof is water.

In one embodiment of the second aspect, the removal reactant or precursor thereof is a gas or a vapour.

In one embodiment of the second aspect, the removal reactant or precursor thereof is not capable of being deposited as a contaminant on the dynode electron-emissive surface.

In one embodiment of the second aspect, the removal reactant or precursor thereof is not carbon-based, is not a hydrocarbon, or does not comprise a carbon atom.

In one embodiment of the second aspect, the means for introducing a removal reactant or precursor thereof on or about one or more dynode emissive surfaces is configured to introduce a gas or a vapour.

In one embodiment of the second aspect, the electron multiplier comprises means for controlling the amount, concentration or partial pressure of a contaminant deposition precursor on or about one or more dynode emissive surfaces.

In one embodiment of the second aspect, the electron multiplier comprises means for increasing the amount, concentration or partial pressure of a removal reactant or precursor thereof on or about one or more dynode emissive surfaces, and means for decreasing the amount, concentration or partial pressure of a contaminant deposition precursor.

In a third aspect, the present invention there is provided a method for removing a contaminant from a dynode electron emissive surface, or inhibiting the build-up of a contaminant on a dynode electron emissive surface, the method comprising the method steps of any embodiment of the first aspect.

In one embodiment of the third aspect, the method is carried out on the electron multiplier of any embodiment of the second aspect.

### BRIEF DESCRIPTION OF THE DRAWINGS

FIG. 1 is a schematic representation of the competing contaminant deposition and chemical removal processes occurring at the surface of a contaminant mass deposited on a dynode surface.

FIG. 2 is a graph showing the relative level of carbon contamination on dynode surfaces of a used (aged) multiplier (dynode #20: last dynode).

FIG. 3 is a graph showing secondary electron yield from (i) a dynode surface of a new Multiplier and those of an aged multiplier (ii) dynode 3, (iii) dynode 10, (iv) dynode 19, and (v) the surface of a specially prepared heavily contaminated dynode covered with a very thick carbon layer (for comparison).

FIG. 4 is a graph showing the theoretical total electron dose incident on each dynode for a used (aged) multiplier.

FIG. 5 is a graph showing depth profiles, taken using Auger Electron Spectroscopy (AES), of the relative amount of carbon contamination on the dynode surfaces of a heavily used multiplier. Dynode 1 corresponds to the first dynode and dynode 19 is the near output.

FIG. 6 is a graph showing the recovery of multiplier gain after gain decay. The recovery was achieved by setting conditions in the multiplier to favour chemical removal processes over contaminant deposition processes.

### DETAILED DESCRIPTION OF THE INVENTION

After considering this description it will be apparent to one skilled in the art how the invention is implemented in various alternative embodiments and alternative applications. However, although various embodiments of the present invention will be described herein, it is understood that these embodiments are presented by way of example only, and not limitation. As such, this description of various alternative embodiments should not be construed to limit the scope or breadth of the present invention. Furthermore, statements of advantages or other aspects apply to specific exemplary embodiments, and not necessarily to all embodiments covered by the claims.

Throughout the description and the claims of this specification the word “comprise” and variations of the word, such as “comprising” and “comprises” is not intended to exclude other additives, components, integers or steps.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment, but may.

It will be appreciated that not all embodiments of the invention described herein have all of the advantages disclosed herein. Some embodiments may have a single advantage, while other may have no advantage at all and are merely a useful alternative to the prior art.

The present invention is predicated at least in part on Applicant's finding that electron-driven carbon build-up on dynode surfaces resulting from the normal operation of an electron multiplier is a cause of detector sensitivity and gain decay over time. It has been found that enhancing electron-driven carbon-removal processes serve to remove deposited carbon-based material, resulting in a net decrease in the carbon deposition rate, and in some cases, actual cleaning of the dynode surface.

Without wishing to be limited by theory in way, it is proposed that the physical processes involved in the build-up of carbon-based materials include deposition of contaminants on the dynode surface induced by the electron flux incident on the dynode. In the case of carbon-based reactants, this process leads to a carbonaceous build-up over the dynode surface, which changes the character of the surface and its properties (including a diminution of secondary electron emissivity). A competing process, which is generally much less efficient, is dissociation of oxygen-based molecules in the environs of the dynode surface by the same electron flux, the dissociation forming free radicals that act as removal reactants that etch the deposited carbon from the dynode surface.

The competing processes can be adjusted to enhance contaminant removal by manipulating the incident electron current density and impact energy. Without wishing to be limited by theory in any way, it is proposed that enhancing the contaminant removal process over the contaminant deposition process is possible because of the potential for each process to proceed at differential rates. A useful differential in the rates may be achieved by over-saturating the contaminant deposition process with electron flux with the excess electrons acting to increase the rate of the contaminant removal process.

Accordingly, the deposition process under normal operating conditions of an electron multiplier has a higher efficiency than the removal process. However, the deposition rate is limited by the arrival rate of a deposition precursor (such as a carbonaceous gas contaminant present in the multiplier) into the dynode surface region under electron radiation. Alternatively, the deposition rate may be limited by the presence of an adsorbate, or an adparticle, or an overlayer on the dynode surface. By contrast, under normal operating conditions the chemical removal process occurs at a lower rate, and does not saturate at elevated electron flux under conditions of high arrival rate of removal reactant molecules at the dynode surface.

The present inventors propose that conditions within an electron multiplier may be altered so as to change from a relatively high rate of net contaminant deposition to (i) a relatively low rate or net contaminant deposition, or (ii) a zero rate of net contaminant deposition, or (iii) a negative rate of net contaminant deposition (i.e. a net reduction in the amount of contaminant deposited on the dynode surface). The change may be achieved because the chemical removal process is of relatively low efficiency, and the deposition processes is saturable by electron current density due to a limitation in contaminant deposition precursor

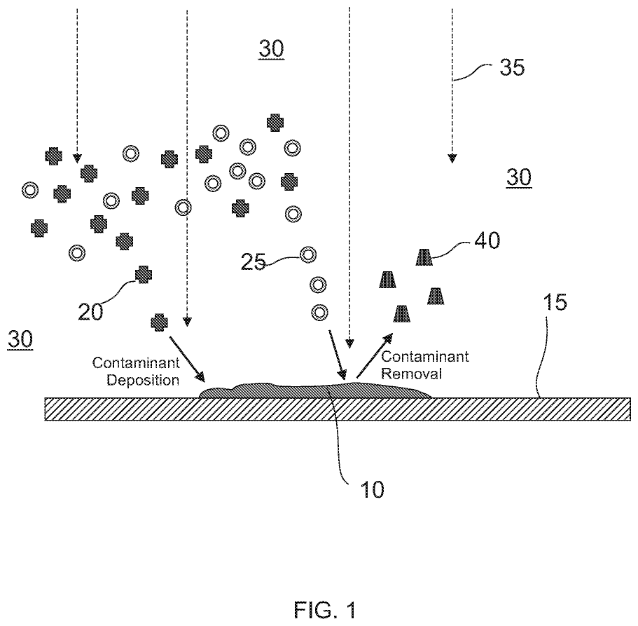

Reference is now made to the diagrammatic representation of FIG. 1 showing the competing processes of contaminant deposition and contaminant removal as they pertain to an existing mass of carbonaceous contaminant material (10) associated with a dynode surface (15). Carbonaceous deposition precursor molecules (20). The deposition precursor molecules include organic (carbon containing) molecules such as hydrocarbons and fluorocarbons ranging from the small (e.g. methane, ethane) to large and complex molecules such proteins, sugars and oils.

Removal reactants (25) are present in the environment (30) surrounding and/or adsorbed on the dynode surface (15). Incoming electrons (35) act on the deposition precursor molecules (20) to chemically alter the precursors so as to become bonded to on the dynode surface (15). This process of contaminant deposition has the effect of growing the contaminant mass (10). While the incoming electrons (35) facilitate the deposition of precursors to cause an increase in the contaminant mass (10), the electrons (35) may have the effect of also contributing to chemical removal of the contaminant mass (10), therefore shrinking the mass (10). Conditions may be manipulated according the present invention to favour the chemical removal process over the deposition process.

Thus, it will be appreciated that the contaminant mass (10) is a dynamic mass in so far as carbonaceous material is turned over by the two competing process of deposition and removal. Whether the contaminant mass (10) grows, shrinks or remains the same size is determined by the balance (or lack of balance) between the deposition and removal processes.

Volatilized removal product (40) is ejected from the contaminant mass (10) and may be carried away by a gas stream. It is possible that volatilized product (40) functions cyclically and contributes as deposition precursor molecules (such as 20), however so long as conditions favour the removal process over the deposition process the net result will be a reduction in contaminant deposition.

Even where the deposition process predominates, any improvement in the rate of removal will at least slow the growth of the contaminant mass (10).

In the scheme of FIG. 1 the oxidant removal reactants (25) facilitate the removal process, but are not involved in the deposition process.

According to the invention, physical configuration and/or setting the operating parameters of an electron multiplier may be used to favour the contaminant removal process. For example, an electrostatic field may be used to spatially focus an electron ‘beam’ onto an area on each dynode surface to increase the current density. In turn, the increased current density saturates the deposition process, but acts to increase the rate of contaminant removal at that region of higher current density. Increasing current density in an area may be achieved, for example, by applying a slightly negative bias at sides of dynodes. The current density may also be controlled by dynode geometry, electrostatic field shape and intensity, or distribution of inter-dynode voltages across multiplier. The skilled person is familiar with other means by which current density may be manipulated, and accordingly will be able to conceive of alternatives without the exercise of inventive faculty.

For magnetic multipliers, the electron beam may be tightly focussed using a magnetic field.

This field may be optionally controlled by a proximal magnetic grid.

Preferably, the electron beam is focussed to create higher current density at the terminal dynodes of the dynode chain, and spread for the first dynodes in the chain. Carbon deposition is more of a problem at the last/terminal dynodes, and so greater electron current densities at these dynodes will assist in regularizing the emissivity of all dynodes in the chain. Where the carbon deposition rate is not saturated at the front end (because the electron current is relatively low) increasing current density may result in an undesirable increase in the contaminant deposition rate.

In addition or alternatively to manipulating the spatial spread of the electron beam, the yields of each dynode may be manipulated by controlling inter-dynode voltages. This strategy may be used to establish relatively high yields at the front end of the multiplier, so the electron current increases quickly down the dynode chain, and the electron beam can be narrowed sooner.

Alternatively, relatively low yields may be used at the front, and so the current increases quickly at the back end, which may facilitate establishing mass transport limited deposition rates. Where particularly high current densities are required to saturate the deposition rate, regardless of how the beam is narrowed, the necessary currents may not be obtained until the last 1 or 2 dynodes.

In exemplary embodiments, a current density of at least about 50, 60, 70, 80, 90, 100, 110, 120, 130, 140, 150, 160, 170, 180, 190, or 200 nA/mm² may be used. Impact energies of between about 5 and 1000 eV may be used.

In addition or alternatively to the manipulation of the incident electron current density of impact energy, the removal process may be favoured by the presence or introduction of a removal reactant or precursor thereof.

In some electron multiplier applications (such as liquid chromatography-mass spectrometry) some gaseous water molecules are present about the dynode surfaces. It is proposed that the presence of such water molecules acts to favour (or to further favour where increased current densities are used, as described supra) the contaminant removal process and therefore slow, prevent or reverse the build-up of carbonaceous contaminants on the dynode surface.

Without wishing to be limited by theory in any way, it is proposed that the water acts as a precursor to a removal reactant. The removal reactant may act as an oxidant in a redox reaction with the deposited contaminant under the electron flux present in an electron multiplier. The removal reactant may volatilize or otherwise degrade the contaminant so as to lead to detachment from the dynode emissive surface. A gas purge may be used to remove the volatilized contaminant from the electron multiplier. Where the volatilized contaminants are not liable to bind to the dynode or the contaminant mass, a gas purge may be unnecessary.

In some embodiments of the method, a removal reactant—or precursor thereof—is deliberately introduced into the electron multiplier. This agent may be introduced where there is no precursor or reactant (such as water) inherently present about the dynode surfaces, or to augment low levels of chemical removal agent inherently present.

For example, the removal reactant or precursor thereof may be an oxidizing gas/vapour such as ozone, O₂, NO₂H₂, Cl₂, SF₆, XeF₂ or CkF₂. Alternatively water may be used, which may act in itself as an oxidant or alternatively function as a precursor and in the presence of an electron flux be converted to a strong oxidant such as the hydroxyl radical. An advantage of water is that it exists as vapour-phase precursor at operational temperatures that adsorbs to, but does not spontaneously etch the depositions. Furthermore, water is entirely safe to handle.

In some applications, only very low levels of the oxidizing gas/vapour are necessary to facilitate the removal process. In this regards amounts of between about 0.01 mPa and about 100 mPa of gas may be used, preferably between about 0.1 mPa and about 10 mPa, more preferably about 1 mPa. These amounts are useful in high vacuum conditions. For lower vacuum conditions larger amounts (such as 10² to 10⁴ Pa) of the oxidant gas may be used.

In some embodiments, the oxidizing gas/vapour is administered so as to prevent the entire vacuum chamber being flooded. Local pressure effects within the vacuum chamber may be exploited to control the passage of water vapour within the chamber. For example, a high pressure region localized about a water dispensing aperture may be established.

The present method may be performed between samples, at regular intervals (daily, weekly, or monthly) at only at normal service intervals (say, bi-annually or annually). Alternatively, the method may be performed during sample analysis by using appropriate operating parameters, and optionally by introducing an oxidant gas into the multiplier either continuously or at intervals.

The present invention will be now more fully described by reference to the following non-limiting example.

### EXAMPLES

### Example 1: Analysis of Dynode Surfaces by Auger Electron Microscopy

The objective of this study was to determine the primary cause(s) of electron multiplier degradation with use over an extended time, with a view toward optimizing detector lifetime in mass spectrometry applications. An understanding of the “aging” process in electron multipliers is a necessary precursor to developing a very long-life mass spectrometer detector. By studying the dynode surfaces of an ETP Multiplier (ETP Electron Multipliers, NSW, Australia), major factors have been identified which influence the deterioration of electron multiplier performance.

While the analysis of the dynode surfaces was performed on a discrete-dynode device, these results may be generalized for any type of electron multiplier detector.

Tests were carried out on a 20-stage Multiplier operated in a vacuum of 3×10 mbar, pumped by a ‘Diffstak’ diffusion pump. A constant current of nitrogen ions was directed into the multiplier aperture and the multiplier high voltage dynamically adjusted so that its gain was held to a constant 1×10⁷ over the 20 hour test. The multiplier output current was held constant at 25 μA.

After accelerated aging for 20 hours, the multiplier was disassembled for analysis. Each dynode of the multiplier was numbered to identify its position in the chain, beginning with the dynode closest to the multiplier input.

Using computer simulation techniques to closely model the operation of a discrete-dynode multiplier, the total dose of electrons incident on the surface of each dynode was estimated (FIG. 4).

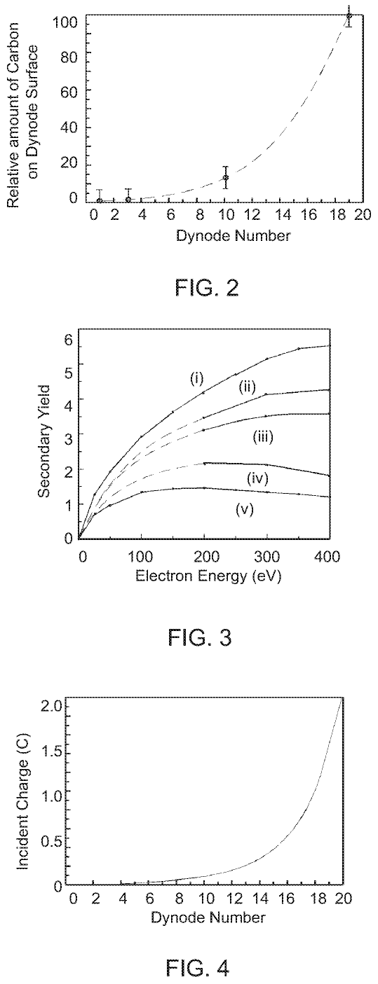

It was found that the dynodes closer to the output of the multiplier are exposed to significantly greater doses of secondary electrons than those dynodes closer to the input. The shape of the curve in FIG. 4 is very close to that seen in FIG. 2.

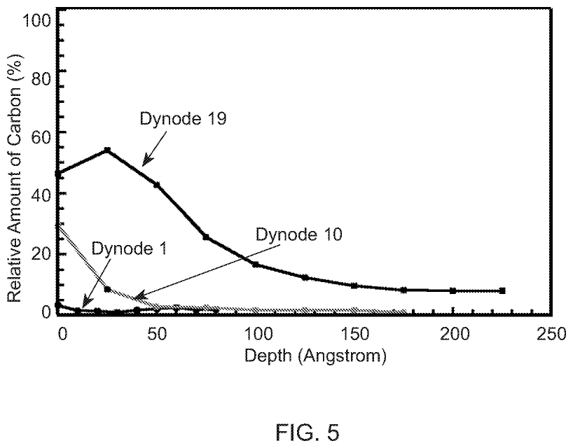

Analysis of the dynode surfaces was conducted using Auger Electron Spectroscopy (AES) which showed the main contaminant observed on the dynode surfaces was carbon. Contaminant levels increased dramatically on the dynodes nearer to the output end of the multiplier (FIG. 5).

All the dynodes of the multiplier were exposed to the same environment for the same time interval. The only difference between the dynodes is the dose of secondary electrons they received during the accelerated aging process. This suggests that the dose per unit area of secondary electrons irradiating the dynode surface is the dominant factor governing the rate at which the dynode surface is contaminated.

The amount of carbon deposited was shown to be directly related to the total accumulated dose of electrons per unit area on the dynode, and not simply the time the multiplier is exposed to the environment in the vacuum chamber, even though the vacuum environment plays a major part in determining the overall life of the detector.

Incident secondary electrons on the dynode surface cause carbon-based molecules in the residual gas to become bonded to the dynode surfaces, reducing the secondary yield. FIG. 4 shows a depth profile of the surface layer of a heavily contaminated dynode. Note the oxide layer, still intact, is buried beneath a thick layer of carbon contamination.

### Example 2: Recovery in Detector Gain after Initial Gain Decay by Removal of Carbonaceous Contaminant

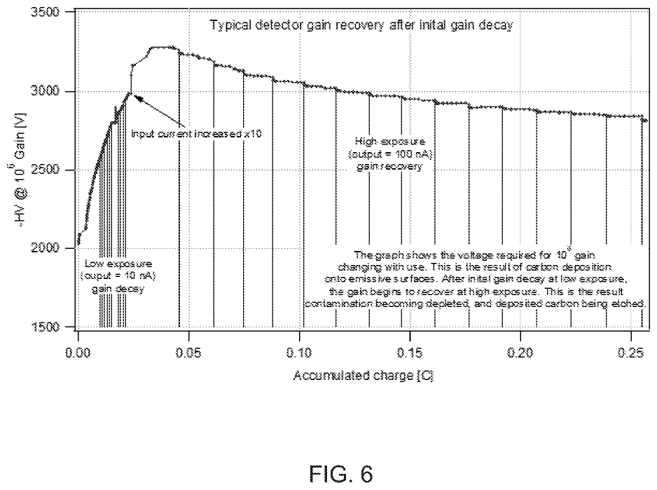

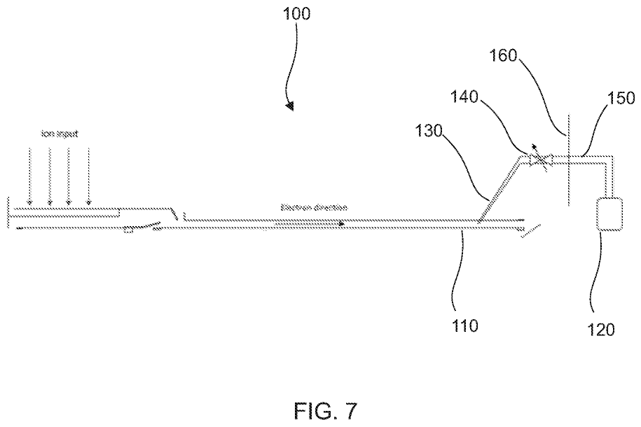

An experiment was conducted to show the removal of carbon deposits from a dynode surface by manipulation of input current, and in the presence of water molecules. Reference is made to FIG. 6.

This apparatus used was a magnetic multiplier (MagneTOF), with a continuous dynode operating in a time of flight mass spectrometer. The base pressure of the analyser chamber was 1×10⁻⁶ mBar.

Voltage supplied to the detector (y-axis) was adjusted over the course of the experiment so as to maintain an overall gain of 10⁶. The output charge accumulated by the detector over time (in Coulombs) is shown on the x-axis.

The graph shows that an increase in voltage is required to offset the gain decay as accumulated charge increases from zero, and at low levels of exposure to electrons. At the point indicated by the arrow, the output current was increased 10-fold from 10 nA to 100 nA (by increasing the input current from 10 fA to 100 fA). After a plateau, gain begins to recover, as shown by the decrease in voltage needed to maintain a gain of 10⁶. This was interpreted as reflective of an increase in electron flux favouring the removal of carbon deposits from the dynode surfaces.

It is well accepted that water is one of, if not the most, prevalent species residual in vacuum chambers. Although the partial pressure of water molecules was not measured, it is assumed that some water was present. It would be expected that by increasing the concentration of water in the camber, a proportionally increase in contaminant removal would be noted, as described in Example 3.

### Example 3: Water-Assisted Removal of Carbonaceous Contaminant

The detector of Example 2 is modified so as to include a capillary tube extending from inside the detector vacuum chamber to outside. The end of the capillary tube outside the chamber is connected to a source of gaseous water. A valve is disposed between the water source and the capillary tube such the amount and timing of gaseous water can be controlled.

The detector is operated as described for Example 2, except that gaseous water is introduced at 1 mPa. Water flow is controlled at about 0.1 sccm, so that the total chamber pressure is not substantially affected but the water is localized on critical surfaces.

The voltage graph resulting is similar to that shown in FIG. 6, except that that the gain recovery portion of the graph (i.e. after initial decay) is steeper and therefore reflective of a more rapid (and possibly more complete) reversal of gain decay.

Reference is made to FIG. 7 which shows a continuous dynode detector 100 configured to introduce water into the vacuum chamber about the terminal region of the dynode plate 110. Liquid water is kept in a gas tight reservoir 120 that is pumped down to the vapour-pressure of water so that the interior of the reservoir 120 is filled by both liquid and gaseous water at a pressure that prevents further vaporisation of the liquid water. As the water vapour is leaked into the multiplier via capillary tube 130 by opening the needle valve 130, the pressure drop in the reservoir 120 causes more liquid water to enter the gas phase, maintaining a constant pressure inside the reservoir (being the vapour pressure of water).

It will be noted that the conduit 150 carrying water from the reservoir 120 to the capillary tube 140 passes sealingly through the vacuum chamber flange 160.

The present apparatus may be configured physically and/or structurally so as to be operable with existing commercially available ICP-MS instruments. By way of example only, the present apparatus may be configured to be operable as an electron multiplier in any of the ICP-MS instruments supplied by Agilent™ such as the models 7800, 7900, 8900 Triple Quadrupole, 8800 Triple Quadrupole, 7700e, 7700x, and 7700s, or PerkinElmer™ such as models NexION2000, N8150045, N8150044, N8150046, and N8150047, or ThermoFisher Scientific such as models iCAP RQ, iCAP TQ, and Element Series, or Shimadzu such as model ICPMS-2030.

The electron multiplier component of the present apparatus has been exemplified by way of linear, discrete dynode multipliers. Given the benefit of the present specification the skilled artisan is enabled to routinely test other types of multiplier types for suitability with the present invention. For example, a continuous (channel/channel plate) dynode may be used in place of a discrete dynode electron multiplier.

It will be appreciated that in the description of exemplary embodiments of the invention, various features of the invention are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment.

Furthermore, while some embodiments described herein include some but not other features included in other embodiments, combinations of features of different embodiments are meant to be within the scope of the invention, and form different embodiments, as would be understood by those in the art. For example, in the following claims, any of the claimed embodiments can be used in any combination.

In the description provided herein, numerous specific details are set forth. However, it is understood that embodiments of the invention may be practiced without these specific details. In other instances, well-known methods, structures and techniques have not been shown in detail in order not to obscure an understanding of this description.

Thus, while there has been described what are believed to be the preferred embodiments of the invention, those skilled in the art will recognize that other and further modifications may be made thereto without departing from the spirit of the invention, and it is intended to claim all such changes and modifications as fall within the scope of the invention. Functionality may be added or deleted from the diagrams and operations may be interchanged among functional blocks. Steps may be added or deleted to methods described within the scope of the present invention.

Although the invention has been described with reference to specific examples, it will be appreciated by those skilled in the art that the invention may be embodied in many other forms.

1. A method for (i) increasing a secondary electron yield of a dynode and/or (ii) decreasing a rate of degradation of electron yield of the dynode, the method comprising:
exposing a dynode electron-emissive surface of the dynode to an electron flux under conditions causing electron-impact induced removal of a contaminant deposited on the dynode electron-emissive surface.

2. The method of claim 1, wherein the conditions are such that the electron-mediated removal is enhanced relative to a contaminant deposition process so as to provide a net decrease in the rate of contaminant deposition and/or a decrease in the amount of contaminant present on the dynode electron-emissive surface.

3. The method of claim 2, wherein the conditions are such that the electron-mediated removal has a higher efficiency than the contaminant deposition process.

4. The method of claim 2 wherein the electron-mediated removal is reliant at least in part on a removal reactant or precursor thereof, the removal reactant or precursor thereof being either inherently present on or about the dynode electron-emissive surface, or deliberately introduced on or about the dynode electron-emissive surface, the removal reactant or precursor thereof being capable under the method conditions of removing or facilitating removal of a contaminant deposited on the dynode electron-emissive surface.

5. The method of claim 4 wherein the removal reactant is capable of donating an electron to the contaminant deposited on the dynode electron-emissive surface, or the precursor is capable of conversion to a removal reactant capable of donating an electron to the contaminant deposited on the dynode electron-emissive surface under the method conditions.

6. The method of claim 4, wherein the removal reactant is involved in a redox reaction with the contaminant deposited on the dynode electron-emissive surface.

7. The method of claim 4, wherein the removal reactant or precursor thereof is water.

8. The method of claim 4 comprising introducing the removal reactant or precursor thereof into a vacuum chamber within which the dynode electron-emissive surface is operable.

9. The method of claim 2, wherein the contaminant deposition process is reliant at least in part on a deposition precursor.

10. The method of claim 9, wherein the deposition precursor is capable of forming a contaminant deposited on the dynode electron-emissive surface, the contaminant deposited on the dynode electron-emissive surface being capable of being involved in a redox reaction with the removal reactant.

11. The method of claim 9, wherein the removal reactant is present on or about the dynode electron-emissive surface at a higher concentration or in higher amounts compared with the deposition precursor.

12. The method of claim 9, wherein the removal reactant and the deposition precursor are both gases, and the removal reactant is present at a higher partial pressure than the deposition precursor.

13. The method of claim 1, wherein the electron flux is controlled so as to enhance electron-mediated removal of a contaminant deposited on the dynode electron-emissive surface over deposition of the contaminant on the dynode electron-emissive surface.

14. The method of claim 1, wherein the electron current density of the electron flux impacting the dynode emissive surface is controlled so as to favour electron-mediated removal of a contaminant over deposition of the contaminant on the dynode electron-emissive surface.

15. The method of claim 14, wherein the electron current density is controlled to an upper or lower limit of a range, within the range limits, whereby any increase in electron density increases the rate of contaminant etching with electron current density but does not proportionally increase rate of contaminant deposition.

16. The method of claim 9 as applied to a series of discrete dynodes in an amplification chain, the method comprising adjusting or setting electron current density differentially between the dynodes in the chain such that the flux density is relatively low for dynodes for which contaminant deposition rate is electron-limited, and relatively high for dynodes for which the contaminant deposition rate is deposition precursor-limited.

17. (canceled)

18. (canceled)

19. An electron multiplier comprising:
one or more dynode electron emissive surfaces; and
a conduit configured to convey a removal reactant or precursor thereof onto or about the one or more dynode electron-emissive surfaces, or an absorbent material disposed on or about the one or more dynode electron emissive surfaces the absorbent material being configured to outgas stored water over a period of time, so as to allow the vacuum chamber to achieve to a desired pressure.

20. The electron multiplier of claim 19, comprising a controller configured to control the amount, concentration or partial pressure of a contaminant deposition precursor on or about one or more dynode emissive surfaces.

21. The electron multiplier of claim 19, comprising means for increasing the amount, concentration or partial pressure of a removal reactant on or about one or more dynode emissive surfaces, and means for decreasing the amount, concentration or partial pressure of a contaminant deposition precursor.

22. A method for removing a contaminant from a dynode electron emissive surface, or inhibiting the build-up of a contaminant on a dynode electron emissive surface, the method comprising:
(i) increasing a secondary electron yield of a dynode having a dynode electro-emissive surface and/or
(ii) decreasing a rate of degradation of electron yield of the dynode,
by exposing the dynode electron-emissive surface to an electron flux under conditions causing electron-impact induced removal of a contaminant deposited on the dynode electron-emissive surface.

23. (canceled)
